(19) United States
(12) Patent Application Publication
(10) Pub. No.: US 2026/0173960 A1
(43) Pub. Date: Jun. 18, 2026

(54) INTEGRATED CIRCUIT PACKAGE AND METHOD OF FORMING THE SAME

(71) Applicant: Taiwan Semiconductor Manufacturing Co., Ltd., Hsinchu (TW)

(72) Inventors: Sung-En Lin, Taoyuan (TW); Chen-Sheng Lin, Taoyuan (TW); Chao-Wen Shih, Zhubei (TW); Kuo-Chiang Ting, Hsinchu (TW)

(21) Appl. No.: 19/176,913

(22) Filed: Apr. 11, 2025

Related U.S. Application Data
(60) Provisional application No. 63/735,698, filed on Dec. 18, 2024.

(51) Int. Cl. H01L 25/065; H01L 21/56; H01L 21/683; H01L 23/00; H01L 23/538; H10B 80/00; H10D 80/30

(52) U.S. Cl. CPC H10W 90/00; H10P 72/74; H10W 70/611; H10W 70/65; H10W 74/01; H10B 80/00; H10D 80/30; H10W 72/0198; H10W 74/10; H10W 74/15; H10W 80/312; H10W 80/327; H10W 90/724; H10W 90/734; H10W 90/794

(57) ABSTRACT

In an embodiment, a method includes forming a wafer comprising a plurality of bottom dies, the plurality of bottom dies comprising a first bottom die and a second bottom die, the first bottom die and the second bottom die being laterally displaced by a first distance; bonding a first top die to the first bottom die in a face-to-face configuration; bonding a second top die to the second bottom die in a face-to-face configuration, the first top die and the second top die being laterally displaced by a second distance, the second distance being different from the first distance; and bonding an interconnection die to the first bottom die and to the second bottom die in a face-to-face configuration, the interconnection die being interposed between the first top die and the second top die.

### PRIORITY CLAIM AND CROSS-REFERENCE

This application claims the benefit of the following provisionally filed U.S. Patent Application: Application No. 63/735,698, filed on Dec. 18, 2024 which application is hereby incorporated herein by reference.

### BACKGROUND

Semiconductor devices are used in a variety of electronic applications, such as personal computers, cell phones, digital cameras, and other electronic equipment, as examples. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along a scribe line. The individual dies are then packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 and 2 illustrate cross-sectional views of intermediate steps during process steps for forming and incorporating semiconductor dies into an integrated chip package, in accordance with some embodiments.

FIGS. 3 and 4 illustrate cross-sectional views of intermediate steps during process steps for forming and incorporating additional semiconductor dies into the integrated chip package, in accordance with some embodiments.

FIGS. 5 through 8 illustrate cross-sectional views of intermediate steps during subsequent process steps for forming the integrated chip package, in accordance with some embodiments.

FIGS. 9A through 9F illustrate plan views of intermediate steps during process steps for forming integrated chip packages, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide methods applied to forming a 3D integrated circuit (3DIC) package, such as a system on integrated chip (SoIC) package. Forming the integrated circuit package (e.g., integrated chip package) includes forming two or more bottom semiconductor dies (e.g., bottom dies) in a wafer (e.g., a reconstructed wafer). One or more top semiconductor dies (e.g., top dies) may be formed and bonded face-to-face (e.g., active sides facing downward) with the bottom semiconductor dies (e.g., active sides facing upward). In addition, an interconnection die may be bonded face-to-face (e.g., active side facing downward) with two or more of the bottom semiconductor dies. The interconnection die electrically couples the corresponding bottom semiconductor dies to one another. A package substrate may also be attached to the structure to provide the integrated chip package with external electrical connection, such as power and/or interconnectivity with other devices.

In accordance with some embodiments, the interconnection die may directly couple three or more of the bottom semiconductor dies. As a result, design of the integrated chip package benefits from greater flexibility in size, shape, and relative placement of the top and bottom semiconductor dies. For example, a pair of bottom semiconductor dies may be located at diagonals from one another or at relatively distal locations in the integrated chip package while still benefitting from having substantially direct communication (e.g., cross-talk). The substantially direct communication may be facilitated by one interconnection die or, perhaps, by more interconnection dies if needed (or desirable) for indirect paths, larger distances, and/or more complex intra-connectivity of the integrated chip package. For example, improved cross-talk between bottom semiconductor dies may be especially helpful for overall functionality such as with calculation efficiency. Embodiments of the integrated chip package with a multi-cross interconnection die as disclosed herein may benefit from improved intra-connectivity as well as flexibility of package design (e.g., relative positions of components, smaller or larger package size, or package shape), which result in greater yield, improved reliability and performance, increased density of features, and/or a smaller size.

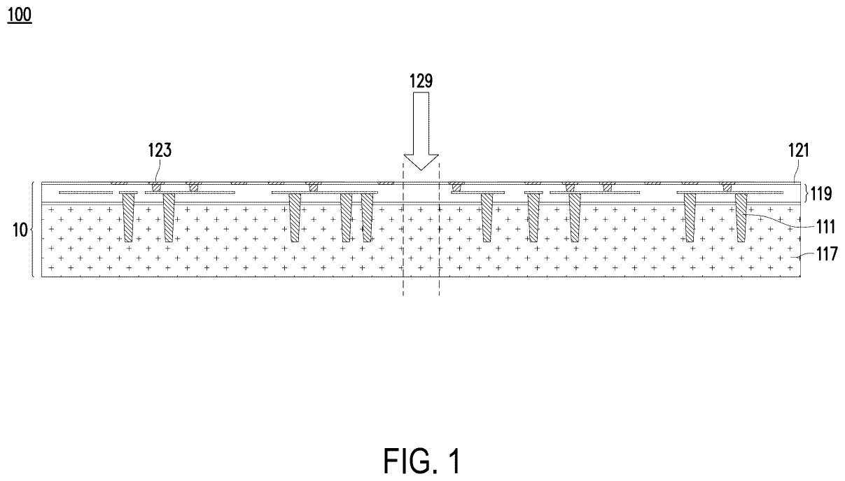

FIGS. 1 through 9F illustrate cross-sectional views (e.g., side views) and plan views (e.g., top-down views) of intermediate steps during a process for forming an integrated chip package 100, in accordance with some embodiments. In FIG. 1, a wafer 10 is illustrated. The wafer 10 comprises bottom semiconductor dies 150. Each of the bottom semiconductor dies 150 may be a logic die (e.g., application processor (AP), central processing unit, microcontroller, etc.), a memory die (e.g., dynamic random access memory (DRAM) die, hybrid memory cube (HBC), a static random access memory (SRAM) die, a wide input/output (wide IO) memory die, a magnetoresistive random access memory (mRAM) die, a resistive random access memory (rRAM) die, etc.), a power management die (e.g., power management integrated circuit (PMIC) dies), a radio frequency (RF) die, a sensor die, a micro-electro-mechanical-system (MEMS) die, a signal processing die (e.g., digital signal processing (DSP) die), a front-end die (e.g., analog front-end (AFE) die), a biomedical die, or the like. Each bottom semiconductor die 150 may also be a System-on-Chip (SoC) die, or the like. The wafer 10 may include a substrate 117 (e.g., a semiconductor substrate), an interconnect structure 119 disposed on the substrate 117, a bonding layer 121 disposed on the interconnect structure 119, and bonding pads 123 disposed in the bonding layer 121 and exposed at the front surface of the wafer 10. The side of the wafer 10 comprising the exposed bonding pads 123 and the bonding layer 121 may also be referred to subsequently as the front side of the wafer 10.

The substrate 117 of the wafer 10 may include a crystalline silicon wafer. The substrate 117 may include various doped regions depending on design requirements (e.g., p-type substrate or n-type substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the substrate 117 may comprise an active layer of a semiconductor-on-insulator (SOI) substrate. The substrate 117 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used.

Active and/or passive devices, such as transistors, diodes, capacitors, resistors, etc., may be formed in and/or on the substrate 117. The devices may be interconnected by the interconnect structure 119. The interconnect structure 119 electrically connects the devices on the substrate 117 to form one or more integrated circuits. The interconnect structure 119 may include one or more dielectric layers (for example, one or more interlayer dielectric (ILD) layers, intermetal dielectric (IMD) layers, or the like) and interconnect wirings or metallization patterns embedded in the one or more dielectric layers. The material of the one or more dielectric layers may include silicon oxide (SiOₓ, wherein x>0), silicon nitride (SiNₓ, wherein x>0), silicon oxynitride (SiOₓN_{y}, wherein x>0 and y >0), or other suitable dielectric material. The interconnect wirings may include metallic wirings. For example, the interconnect wirings include copper wirings, copper pads, aluminum pads or combinations thereof that are formed by one or more single damascene processes, dual damascene processes, or the like. The side of the wafer 10 comprising an exposed back side surface of the substrate 117 may also be referred to subsequently as the back side of the wafer 10.

The bonding layer 121 may comprise a dielectric layer. Bonding pads 123 are embedded in the bonding layer 121, and the bonding pads 123 allow connections to be made to the interconnect structure 119 and the devices on the substrate 117. The material of the bonding layer 121 may be silicon oxide (SiOₓ, wherein x>0), silicon nitride (SiNₓ, wherein x>0), silicon oxynitride (SiOₓN_{y}, wherein x>0 and y >0), tetraethyl orthosilicate (TEOS), or other suitable dielectric material, and the bonding pads 123 may comprise conductive pads (e.g., copper pads), conductive vias (e.g., copper vias), or combinations thereof. The bonding layer 121 may be formed by depositing a dielectric material over the interconnect structure 119 using a chemical vapor deposition (CVD) process (e.g., a plasma enhanced CVD process or other suitable process); patterning the dielectric material to form the bonding layer 121 including openings or through holes; and filling conductive material in the openings or through holes defined in the bonding layer 121 to form the bonding pads 123 embedded in the bonding layer 121.

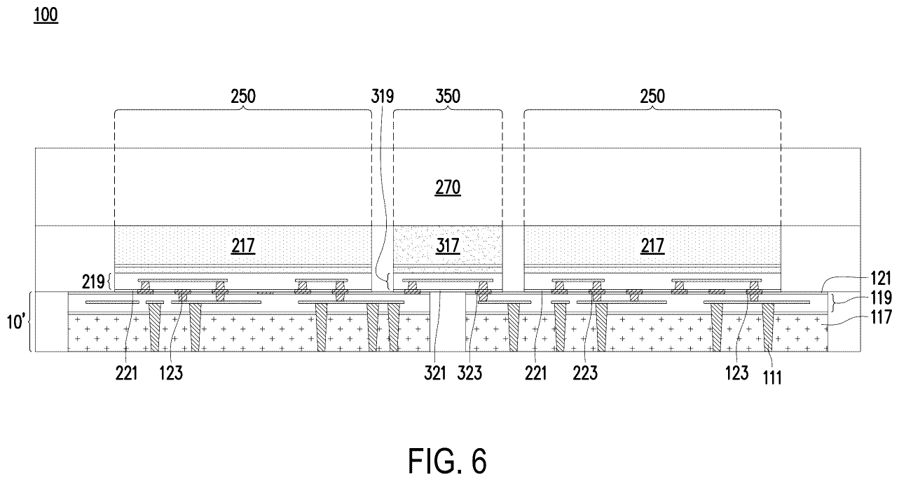

The bottom semiconductor dies 150 further include through substrate vias (TSVs) 111 which may be electrically connected to the metallization patterns in the interconnect structure 119. For example, the TSVs 111 may be formed by forming recesses in the substrate 117 by, for example, etching, milling, laser techniques, a combination thereof, and/or the like. A thin barrier layer may be conformally deposited over the front side of the substrate 117 and in the openings, such as by chemical vapor deposition (CVD), atomic layer deposition (ALD), physical vapor deposition (PVD), thermal oxidation, a combination thereof, and/or the like. The barrier layer may comprise a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the substrate 117 by, for example, chemical mechanical polishing. Thus, in some embodiments, the TSVs 111 may comprise a conductive material and a thin barrier layer between the conductive material and the substrate 117. In subsequent processing steps, the substrate 117 may be thinned to expose the TSVs 111 (see FIG. 6). After thinning, the TSVs 111 provide electrical connection from a back side of the substrate 117 to a front side of the substrate 117. In various embodiments, the back side of the substrate 117 may refer to a side of the substrate 117 opposite to the devices and the interconnect structure 119 while the front side of the substrate 117 may refer to a side of the substrate 117 on which the devices and the interconnect structure 119 are disposed.

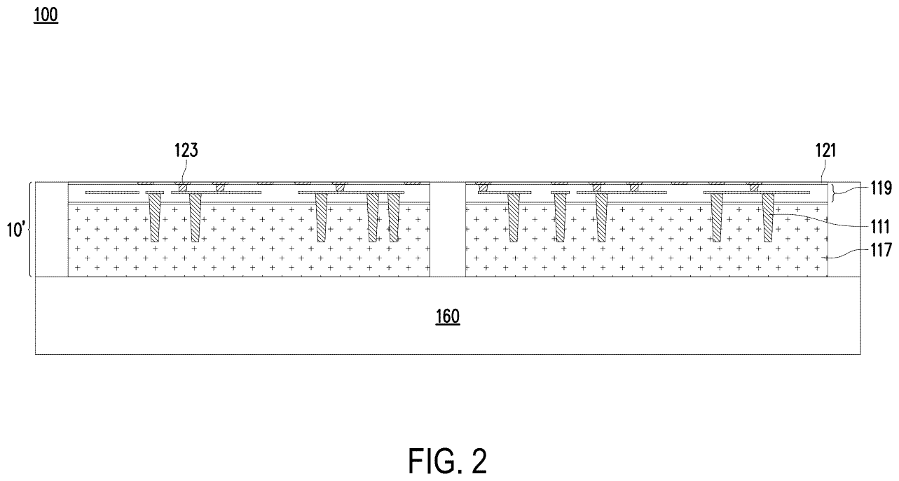

Optionally, a dicing process will be performed along a scribe line 129 of the wafer 10 (see FIG. 2). The dicing process singulates the bottom semiconductor dies 150 from each other along the scribe line 129. The scribe line 129 is disposed between adjacent bottom semiconductor dies 150 which may be referred to as bottom dies. The dicing process may comprise, for example, a blade dicing process using an abrasive disc or blade saw rotating at high speed to cut along the scribe line 129. The blade tip may comprise abrasive grit or a thin diamond layer.

In FIG. 2, if the dicing process is performed to singulate the bottom semiconductor dies 150, and a plurality of the bottom semiconductor dies 150 may be formed into a reconstructed wafer 10′. For example, the bottom semiconductor dies 150 may be attached to a substrate 160, and an encapsulant 132 may be formed over and between the bottom semiconductor dies 150 to encapsulate the bottom semiconductor dies 150 in the encapsulant 132. The encapsulant 132 may be formed using compression molding, transfer molding, spin-coating, or the like. The encapsulant 132 may be an epoxy or a molding compound resin such as polyimide, polyphenylene sulfide (PPS), polyetheretherketone (PEEK), poly ether sulphone (PES), a heat resistant crystal resin, combinations of these, or the like. In some embodiments, the encapsulant 132 forms bonds with the semiconductor substrates (e.g., the substrates 117) of the bottom semiconductor dies. As illustrated, the encapsulant may be coterminous with the substrates 117. Note that some or all of the bottom semiconductor dies 150 may be a same type of device die (e.g., formed in a same wafer 10 or in multiple wafers 10 of a same type) or may include multiple types of device dies.

After the formation of the encapsulant 132, a planarization process is performed to remove excess portions of the encapsulant 232, and to expose top surfaces of the bottom semiconductor dies 150. The planarization process may comprise a grinding process, a CMP process, or the like. As illustrated, the planarization process may result in top surfaces of the bottom semiconductor dies 150 being level with top surfaces of the encapsulant 132. In some embodiments, the planarization process may expose the bonding layer 121 and the bonding pads 123.

In some embodiments (not specifically illustrated), the bonding layer 121 and the bonding pads 123 may be formed on the interconnect structure 119 after forming the reconstructed wafer 10′. For example, the bonding layer 121 may be formed to extend across the front surface (e.g., the front side) of the wafer 10′ after formation of the encapsulant 132. In addition, the bonding pads 123 are embedded in the bonding layer 121 directly over and electrically coupled to the interconnect structures 119 of the bottom semiconductor dies 150.

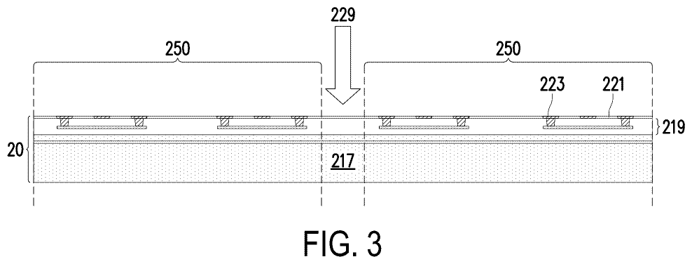

In FIG. 3, a wafer 20 is illustrated. The wafer 20 comprises top semiconductor dies 250. Each of the top semiconductor dies 250 may be a logic die, a memory die, a power management die, a radio frequency (RF) die, a sensor die, a micro-electro-mechanical-system (MEMS) die, a signal processing die, a front-end die, a biomedical die, or the like, similarly as described above in connection with the bottom semiconductor dies 150. Each top semiconductor die 250 may also be a System-on-Chip (SoC) die, or the like.

The materials and formation processes of the features in the wafer 20 (e.g., the top semiconductor dies 250) may be found by referring to the like features in the wafer 10/10′ (e.g., the bottom semiconductor dies 150), with the like features in the bottom semiconductor dies 150 starting with number “1,” which features correspond to the features in the top semiconductor dies 250 and having reference numerals starting with number “2.” For example, the top semiconductor dies 250 may include a substrate 217 having devices (e.g., transistors, capacitors, diodes, resistors, or the like) formed thereon and an interconnect structure 219. The interconnect structure 219 electrically connects the devices on the substrate 217 to form one or more integrated circuits. The interconnect structure 219 includes one or more dielectric layers (for example, one or more interlayer dielectric (ILD) layers, intermetal dielectric (IMD) layers, or the like) and interconnect wirings or metallization patterns embedded in the one or more dielectric layers.

A bonding layer 221 is disposed on the interconnect structure 219, and bonding pads 223 are disposed in the bonding layer 221. The bonding pads 223 allow connections to be made to the interconnect structure 219 and the devices on the substrate 217. The bonding layer 221 may comprise a dielectric layer and the bonding pads 223, similarly as described above in connection with the bonding layer 121 and the bonding pads 123 of the bottom semiconductor dies 150.

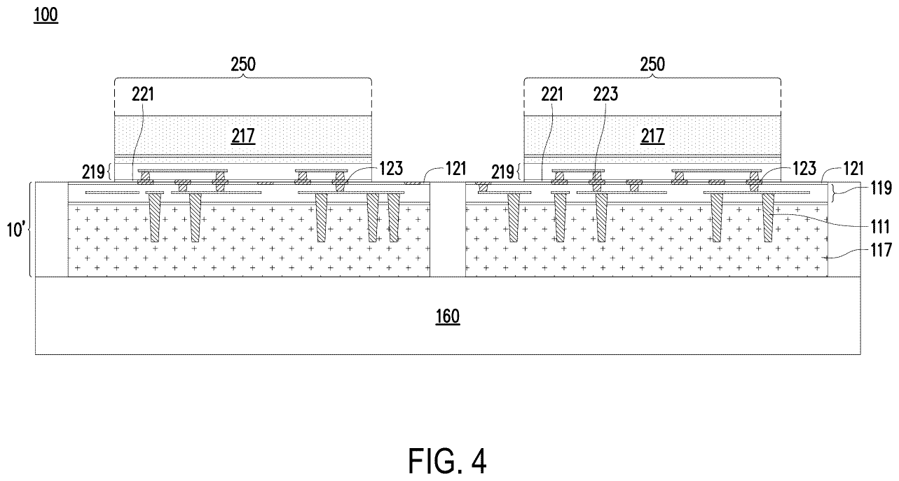

Similarly as described above, a dicing process will be performed along a scribe line 229 of the wafer 20 (see FIG. 4). The dicing process singulates the top semiconductor dies 250 from each other along the scribe line 229. The scribe line 229 is disposed between adjacent top semiconductor dies 250 which may be referred to as top dies. The dicing process may comprise, for example, a blade dicing process using an abrasive disc or blade saw rotating at high speed to cut along the scribe line 229. The blade tip may comprise abrasive grit or a thin diamond layer.

In FIG. 4, the top semiconductor dies 250 are singulated and bonded to the reconstructed wafer 10′ illustrated in FIG. 2. As discussed above, the reconstructed wafer 10′ may include a plurality of the bottom semiconductor dies 150. In particular, the top semiconductor dies 250 are bonded to the wafer 10′ (e.g., the bottom semiconductor dies 150), for example, using a direct bonding process, which may result in a metal-to-metal and dielectric-to-dielectric bonding configuration. The top semiconductor dies 250 may be disposed face down such that front sides (e.g., active sides) of the top semiconductor dies 250 face the wafer 10′ and back sides of the top semiconductor dies 250 face away from the wafer 10′. In other words, the top semiconductor dies 250 may have a face-to-face configuration with the bottom semiconductor dies 150. The top semiconductor dies 250 are bonded to the bonding layers 121 on the front side of the wafer 10′ and the bonding pads 123 in the bonding layers 121. For example, the bonding layer 221 of the top semiconductor dies 250 may be directly bonded to the bonding layer 121 of the bottom semiconductor dies 150, and the bonding pads 223 of the top semiconductor dies 250 may be directly bonded to the bonding pads 123 of the bottom semiconductor dies 150. In an embodiment, the bond between the bonding layer 121 and the bonding layer 221 may be an oxide-to-oxide bond, or the like. The direct bonding process further directly bonds the bonding pads 223 of the top semiconductor dies 250 to the bonding pads 123 of the bottom semiconductor dies 150 through direct metal-to-metal bonding and dielectric-to-dielectric bonding. In some embodiments, corresponding bonding pads 223, 123 may overhang one another, thereby resulting in the formation of dielectric-to-metal bonds between bonding layer 221 and bonding pads 123 and/or between bonding layer 121 and bonding pads 223. Thus, electrical connection between the top semiconductor dies 250 and the wafer 10′ (e.g., the bottom semiconductor dies 150) is provided by the physical connection of the bonding pads 123 to the bonding pads 223.

As an example, the direct bonding process starts with aligning the top semiconductor dies 250 with respective bottom semiconductor dies 150 of the wafer 10′, for example, by applying a surface treatment to one or more of the bonding layer 121 or the bonding layer 221. The surface treatment may include a plasma treatment. The plasma treatment may be performed in a vacuum environment. After the plasma treatment, the surface treatment may further include a cleaning process (e.g., a rinse with deionized water, or the like) that may be applied to one or more of the bonding layer 121 or the bonding layer 221. The direct bonding process may then proceed to aligning the bonding pads 223 to the bonding pads 123. Next, the direct bonding includes a pre-bonding step, during which the top semiconductor dies 250 are put in contact with the wafer 10′. The pre-bonding may be performed at room temperature (e.g., between about 21° C. and about 25° C.). The direct bonding process continues with performing an anneal, for example, at a temperature between about 150° C. and about 400° C. for a duration between about 0.5 hours and about 3 hours, so that the metal in bonding pads 123 (e.g., copper) and the metal of the bonding pads 223 (e.g., copper) inter-diffuses to each other, and hence the direct metal-to-metal bonding is formed. Although one of the top semiconductor dies 250 is illustrated as being bonded to each bottom semiconductor die 150, other embodiments may include any number of semiconductor dies 250 bonded to each bottom semiconductor die 150.

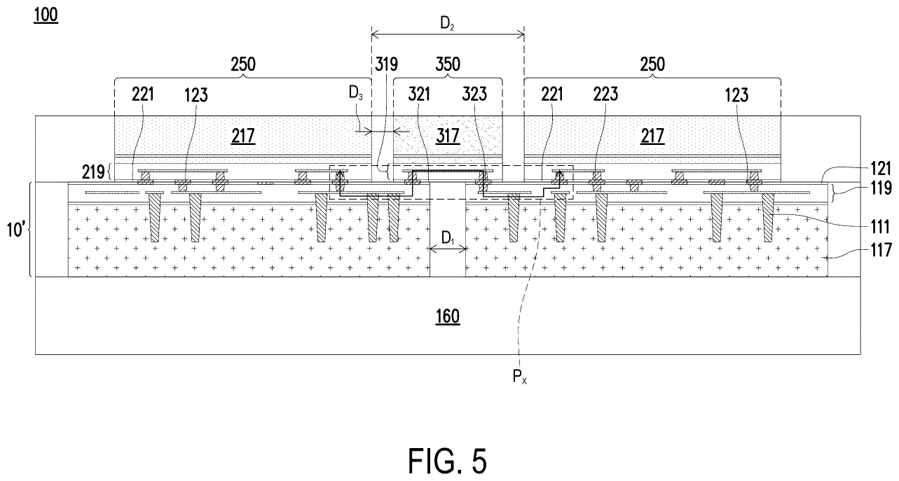

In FIG. 5, interconnection dies 350 are bonded to the wafer 10′ (e.g., the bottom semiconductor dies 150), for example, using a direct bonding process, similarly as described in connection with attaching the top semiconductor dies 250 to the bottom semiconductor dies 150 (see FIG. 4). Each interconnection die 350 may be a local silicon interconnect (LSI), a large scale integration package, an interposer die, or the like. For example, the interconnection dies 350 may be bridge dies. In the illustrated cross-section, one interconnection die 350 is attached over a package region of the wafer 10′. The interconnection dies 350 may be disposed face down such that front sides (e.g., active sides) of the interconnection dies 350 face the wafer 10′ and back sides of the interconnection dies 350 face away from the wafer 10′. In other words, the interconnection dies 350 may have a face-to-face configuration with the bottom semiconductor dies 150.

Because the interconnection dies 350 electrically couple at least two bottom semiconductor dies 150 to one another, the interconnection dies 350 may be referred as being electrically interposed (e.g., directly electrically interposed) between those corresponding bottom semiconductor dies 150. As illustrated, electrical path Pₓ provides a generic example of how the interconnection die 350 may couple two bottom semiconductor dies 150. And those bottom semiconductor dies 150 may also be coupled to corresponding top semiconductor dies 250.

The materials and formation processes of the features in the interconnection dies 350 may be found by referring to the like features in the bottom semiconductor dies 150, 250, with the like features in the bottom semiconductor dies 150 starting with number “1” and the like features in the top semiconductor dies 250 starting with number “2,” which features correspond to the features in the interconnection dies 350 and having reference numerals starting with number “3.” For example, the interconnection dies 350 may include a substrate 317 and an interconnect structure 319 formed thereon. In some embodiments, the interconnection dies 350 are free of active devices, such as transistors. The interconnection dies 350 may or may not include passive devices (e.g., capacitors, diodes, resistors, or the like) formed in or on a surface of the substrate 317. In other embodiments, the interconnection dies 350 may include active devices such as transistors and the like. The interconnect structure 319 may electrically connect the devices (if present) on the substrate 317 to form one or more integrated circuits. The interconnect structure 319 includes one or more dielectric layers (for example, one or more interlayer dielectric (ILD) layers, intermetal dielectric (IMD) layers, or the like) and interconnect wirings or metallization patterns embedded in the one or more dielectric layers.

The bonding processes of the interconnection dies 350 may be performed similarly as described above in connection with bonding the top semiconductor dies 250 to the bottom semiconductor dies 150. For example, the interconnection dies 350 may also include a bonding layer 321 disposed on the interconnect structure 319, and bonding pads 323 disposed in the bonding layer 321 and exposed at the front surface of the interconnection die 350. The side of the interconnection die 350 comprising the bonding pads 323 and the bonding layer 321 may also be referred to subsequently as the front side of the interconnection die 350. As such, the interconnection dies 350 may be attached using direct bonding processes such that metal-to-metal bonds are formed between the bonding pads 323 and the bonding pads 123, and dielectric-to-dielectric bonds are formed between the bonding layer 321 and the bonding layer 121. In some embodiments, corresponding bonding pads 323, 123 may overhang one another, thereby resulting in the formation of dielectric-to-metal bonds between bonding layer 321 and bonding pads 123 and/or between bonding layer 121 and bonding pads 323.

In addition, an encapsulant 232 is formed over the wafer 10′, the top semiconductor dies 250, and the interconnection dies 350 in order to encapsulate each of the top semiconductor dies 250 and the interconnection dies 350. The encapsulant 232 may be formed using compression molding, transfer molding, spin-coating, or the like. The encapsulant 232 may be an epoxy or a molding compound resin such as polyimide, polyphenylene sulfide (PPS), polyetheretherketone (PEEK), poly ether sulphone (PES), a heat resistant crystal resin, combinations of these, or the like.

After the formation of the encapsulant 232, a planarization process is performed to remove excess portions of the encapsulant 232. Optionally, the planarization process may expose top surfaces of the top semiconductor dies 250 (e.g., the substrates 217). The planarization process may comprise a grinding process, a CMP process, or the like. As illustrated 4, the planarization process may result in top surfaces of the top semiconductor dies 250 being level with top surfaces of the encapsulant 232.

Although the interconnection die 350 is illustrated in FIG. 5 as being bonded and electrically coupled to two bottom semiconductor dies 150, some of the interconnection dies 350 may be bonded to more than two of the bottom semiconductor dies 150. For example, as discussed in greater detail below, some of the interconnection dies 350 may be bonded to and electrically couple three or more of the bottom semiconductor dies 150, such as four, five, or size bottom semiconductor dies 150. The interconnection die 350 may be placed, e.g., over corners of the underlying bottom semiconductor dies 150. In particular, in addition to the adjacent (e.g., neighboring) bottom semiconductor dies 150 being coupled by an overlying interconnection die 350, other bottom semiconductor dies 150 may also be coupled by the interconnection die 350. As a result, a single interconnection die 350 may facilitate cross-communication (e.g., cross-talk) between each of the respective bottom semiconductor dies 150. The interconnection dies 350 may also be referred to as multi-cross-talk dies, multi-cross LSI dies, or the like.

Still referring to FIG. 5, a gap between adjacent bottom semiconductor dies 150 may have a lateral distance D₁. In addition, a gap between adjacent top semiconductor dies 250 may have a lateral distance D₂. Further, a gap between an interconnection die 350 and an adjacent top semiconductor die 250 may have a lateral distance D₃. As illustrated, in some embodiments, the distance D₁ between adjacent bottom semiconductor dies 150 may be greater than the distance D₂ between adjacent top semiconductor dies 250 which are bonded to the corresponding bottom semiconductor dies 150. After bonding the interconnection die 350 to the adjacent bottom semiconductor dies 150, the distance D₃ with one of the adjacent top semiconductor dies 250 may be substantially equal to or less than the distance D₁. In other embodiments, the distance D₃ may be greater than the distance D₁.

In FIG. 6, a substrate 270 is attached over the top semiconductor dies 250, and a thinning process is performed on a back side of the substrate 117. The substrate 270 may comprise a suitable material such as silicon. The thinning process is performed to expose the TSVs 111 through the substrate 117. The thinning process of the back side of the substrate 117 may be performed by a planarization process such as CMP, grinding, or etching. The thinning process may result in surfaces of the TSVs 111 being level with surfaces of the back side of the substrate 117.

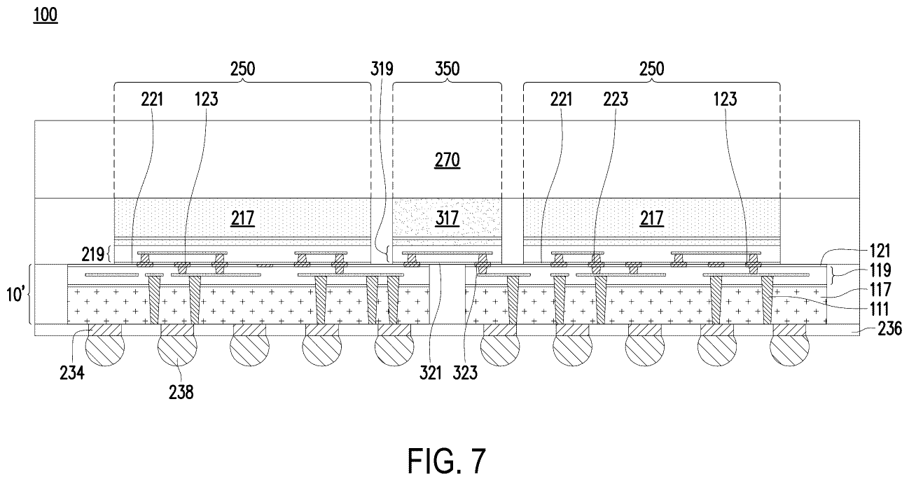

In FIG. 7, a dielectric layer 234 is formed on the back side of the substrate 117 and on the exposed surfaces of the TSVs 111. The dielectric layer 234 may comprise silicon oxide, silicon nitride, silicon carbide, silicon oxynitride, low-K dielectric material, such as phosphosilicate glass (PSG), borophosphosilicate glass (BPSG), fluorosilicate glass (FSG), SiOxCy, Spin-On-Glass, Spin-On-Polymers, silicon carbon material, compounds thereof, composites thereof, combinations thereof, or the like. The dielectric layer 234 may be deposited by any suitable method, such as, CVD, PECVD, spinning, or the like.

Metallization patterns 236 may be formed in the dielectric layer 234, for example, by using photolithography techniques to deposit and pattern a photoresist material on the dielectric layer 234 to expose portions of the dielectric layer 234 that are to become the metallization patterns 236. An etch process, such as an anisotropic dry etch process, may be used to create openings in the dielectric layer 234 corresponding to the exposed portions of the dielectric layer 234. The openings in the dielectric layer 234 may expose the TSVs 111. A seed layer (not separately illustrated) is formed over the exposed surfaces of the dielectric layer 234 and in the openings in the dielectric layer 234. In some embodiments, the seed layer is a metal layer, which may be a single layer or a composite layer including a plurality of sub-layers formed of different materials. In some embodiments, the seed layer includes a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the metallization patterns 236. The patterning forms openings through the photoresist to expose the seed layer. A conductive material is then formed in the openings and on the exposed portions of the seed layer. The conductive material may be formed by plating, such as electroplating, electroless plating, or the like. The conductive material may include a metal, such as copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process. The remaining portions of the seed layer and conductive material in the dielectric layer 234 form the metallization patterns 236. These metallization patterns 236 will be used to electrically connect the TSVs 111 to external devices. In some embodiments, the metallization patterns 236 may also include under Bump Metallizations (UBMs).

In addition, conductive connectors 238 are formed on the metallization patterns 236. For example, the conductive connectors 238 may be formed such that they are disposed on the metallization patterns 236, and are electrically coupled to the bottom semiconductor dies 150 through the TSVs 111 and, therefore, electrically connected to the top semiconductor dies 250 and the interconnection dies 350. The conductive connectors 238 may comprise controlled collapse chip connection (C4) bumps, ball grid array (BGA) connectors, solder balls, or the like. The conductive connectors 238 may comprise a conductive material such as solder, copper, aluminum, gold, nickel, silver, palladium, tin, the like, or a combination thereof. In some embodiments, the conductive connectors 238 are formed by initially forming a layer of solder through evaporation, electroplating, printing, solder transfer, ball placement, or the like. Once a layer of solder has been formed on the structure, a reflow may be performed in order to shape the material into the desired bump shapes.

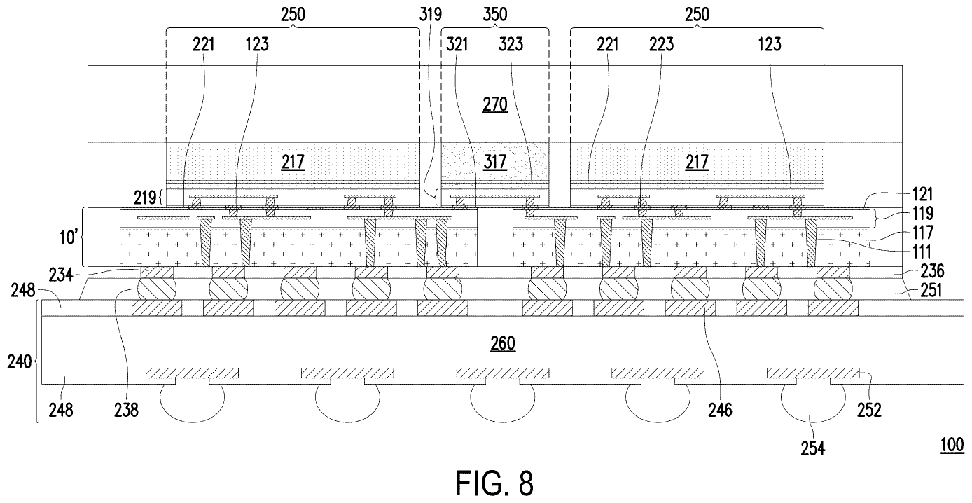

The conductive connectors 238 will be used to bond to the integrated chip package 100 to an additional electrical component, which may be a semiconductor substrate, a package substrate, a Printed Circuit Board (PCB), or the like (see FIG. 8).

In FIG. 8, a package substrate 240 is coupled to the integrated chip package 100. The package substrate 240 may comprise an interposer, a package, a core substrate, a coreless substrate, a printed circuit board (PCB), or the like. In an embodiment, the package substrate 240 includes a substrate core 260 and bond pads 246 over the substrate core 260. The substrate core 260 may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core 260 may be an SOI substrate. Generally, an SOI substrate includes a layer of a semiconductor material such as epitaxial silicon, germanium, silicon germanium, SOI, SGOI, or combinations thereof. The substrate core 260 is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for substrate core 260.

The substrate core 260 may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core 260 may also include metallization layers and vias (not shown), with the bond pads 246 being physically and/or electrically coupled to the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material and may be formed through any suitable process (such as deposition, damascene, dual damascene, or the like). In some embodiments, the substrate core 260 is substantially free of active and passive devices.

In some embodiments, the conductive connectors 238 are reflowed to attach the integrated chip package 100 to the bond pads 246. The conductive connectors 238 electrically and/or physically couple the package substrate 240, including metallization layers in the substrate core 260, to the integrated chip package 100. In some embodiments, a solder resist 248 is formed on the substrate core 260. The conductive connectors 238 may be disposed in openings in the solder resist 248 to be electrically and mechanically coupled to the bond pads 246. The solder resist 248 may be used to protect areas of the substrate core 260 from external damage.

The conductive connectors 238 may have an epoxy flux (not shown) formed thereon before they are reflowed with at least some of the epoxy portion of the epoxy flux remaining after the integrated chip package 100 is attached to the package substrate 240. This remaining epoxy portion may act as an underfill to reduce stress and protect the joints resulting from reflowing the conductive connectors 238. In some embodiments, an underfill 251 may be formed between the integrated chip package 100 and the package substrate 240, and surrounding the conductive connectors 238. The underfill 251 may be formed by a capillary flow process after the coupling of the integrated chip package 100 to the package substrate 240 or may be formed by a suitable deposition method before the package substrate 240 is coupled to the integrated chip package 100.

In an embodiment, the package substrate 240 may comprise bond pads 252 over the substrate core 260. Conductive connectors 254 may be coupled to the bond pads 252 to allow for the electrical coupling of the package substrate 240 to external circuits or devices. The conductive connectors 254 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 254 may include a conductive material such as solder, copper, aluminum, gold, nickel, silver, palladium, tin, the like, or a combination thereof. In some embodiments, the solder resist 248 is formed on the substrate core 260 and the conductive connectors 254 may be disposed in openings in the solder resist 248 to be electrically and mechanically coupled to the bond pads 252. The solder resist 248 may be used to protect areas of the substrate core 260 from external damage.

In some embodiments, passive devices (e.g., surface mount devices (SMDs), not shown) may also be attached to the package substrate 240 (e.g., to the bond pads 246). For example, the passive devices may be bonded to a same surface of the package substrate 240 as the conductive connectors 238.

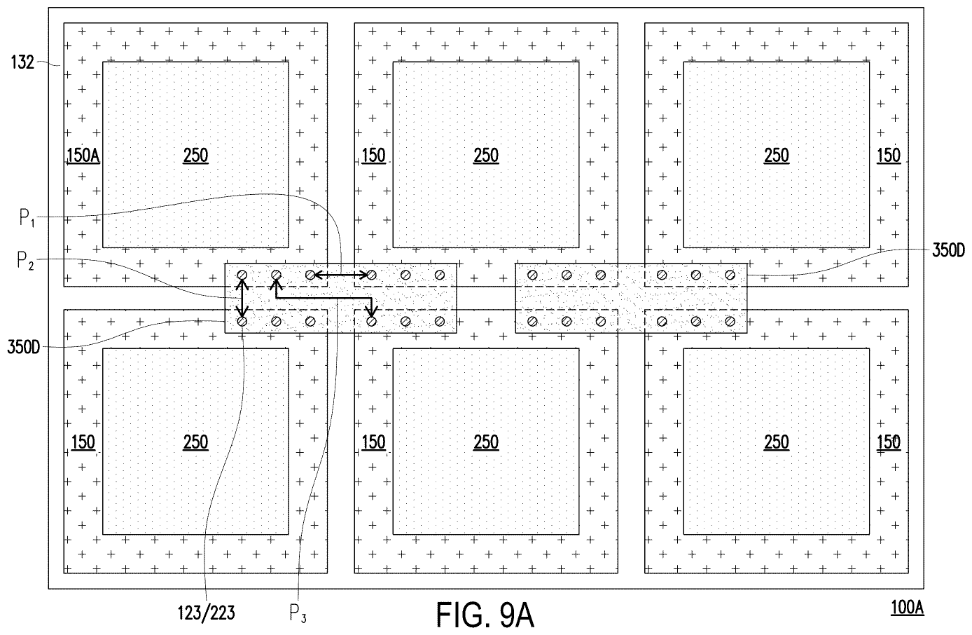

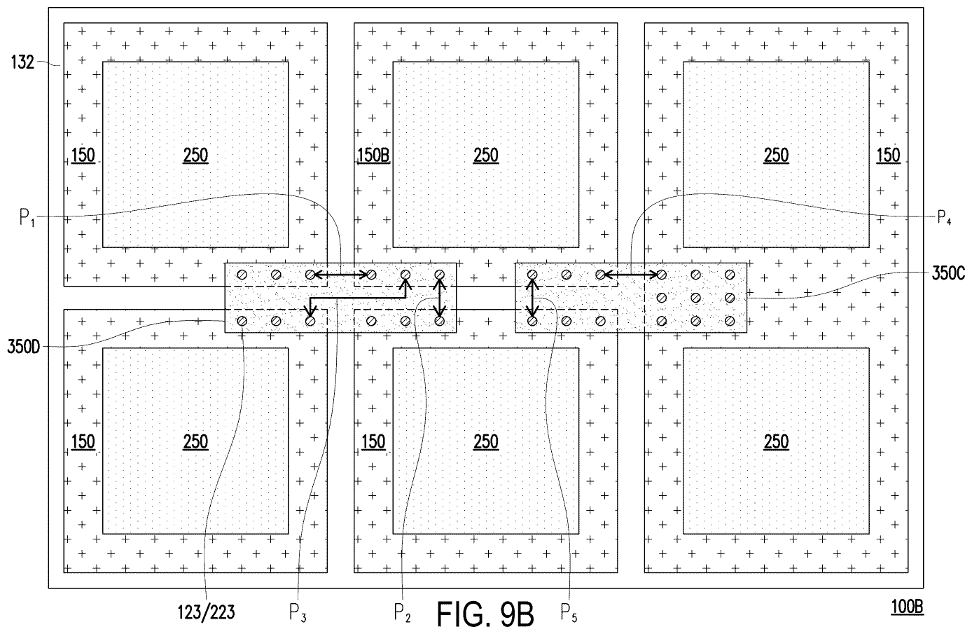

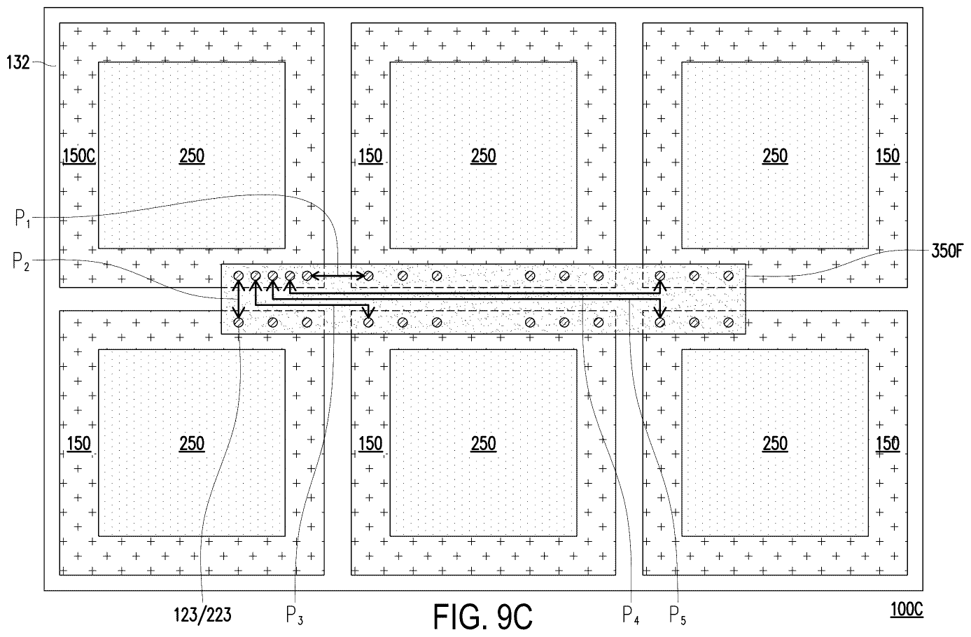

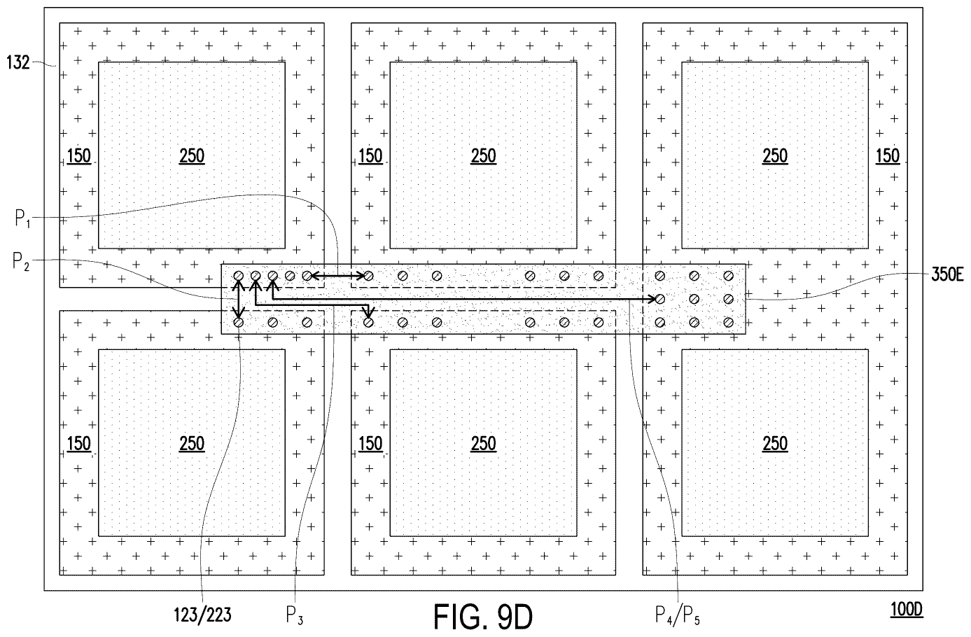

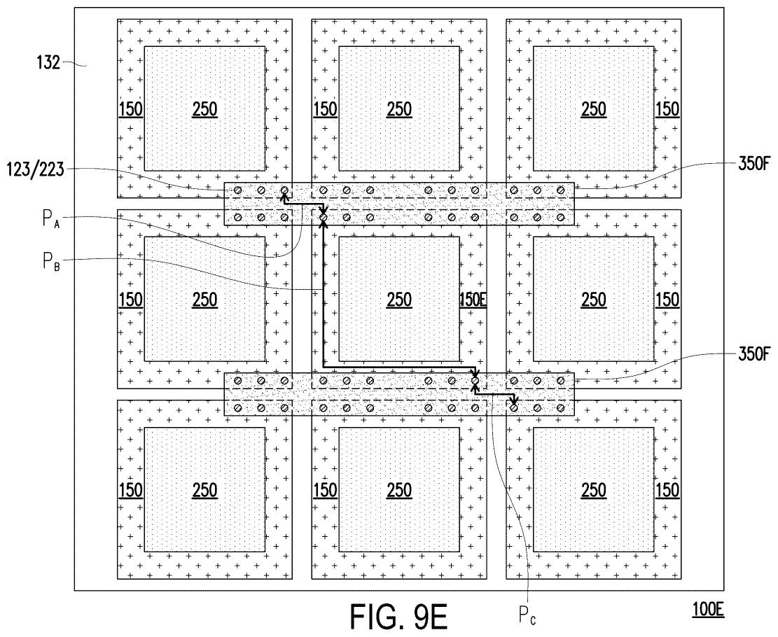

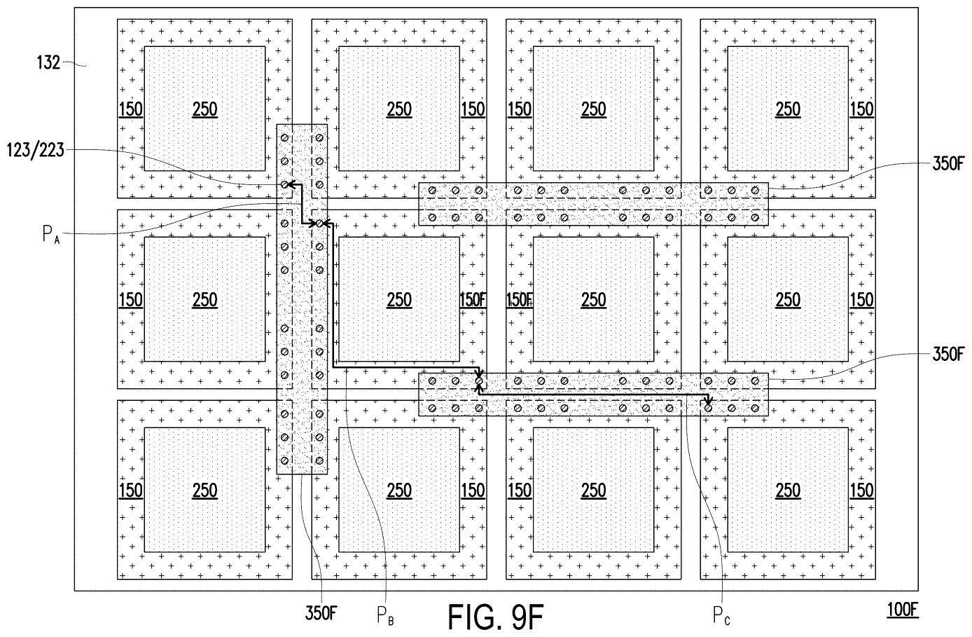

FIGS. 9A through 9F illustrate plan views (e.g., top-down views) of exemplary embodiments of the integrated chip package 100. In particular, the bottom semiconductor dies 150 (e.g., the wafer 10′), the top semiconductor dies 250, and the interconnection dies 350 are illustrated, in accordance with various embodiments.

In FIG. 9A, integrated chip package 100A is illustrated wherein at least one of the interconnection dies 350 is a quadrant interconnection die 350D which is electrically coupled to four bottom semiconductor dies 150. As illustrated, the quadrant interconnection die 350D may directly electrically couple (e.g., directly couple) an exemplary bottom semiconductor die 150A with up to three other bottom semiconductor dies 150. As such, the exemplary bottom semiconductor die 150A may directly communicate with three other bottom semiconductor dies 150. In the illustrated embodiment, the exemplary bottom semiconductor die 150A is able to communicate with two directly adjacent bottom semiconductor dies 150 as well as one diagonal bottom semiconductor die 150. Note that the interconnection die 350 may provide electrical coupling to some or all possible pairs of the bottom semiconductor dies 150 which the interconnection die 350D overlaps (e.g., is bonded to). For example, the quadrant interconnection die 350D may facilitate up to six communication couplets between the corresponding bottom semiconductor dies 150.

Further illustrated are exemplary electrical paths between the exemplary bottom semiconductor die 150A and other bottom semiconductor dies 150. For example, path P₁ and path P₂ communicate through a first interconnection die 350D (e.g., on the left) to two adjacent bottom semiconductor dies 150. In addition, path P₃ is also made through the first interconnection die 350D to a diagonal bottom semiconductor die 150. Moreover, analogous electrical paths may be identified between the middle column bottom semiconductor dies 150 to the right column bottom semiconductor dies 150. As such, all pairs of the bottom semiconductor dies 150 are within one or two degrees of communication through the quadrant interconnection dies 350D.

In FIG. 9B, integrated chip package 100B is illustrated wherein at least one of the interconnection dies 350 is a trient interconnection die 350C which is electrically coupled to three bottom semiconductor dies 150. As illustrated, the treint interconnection die 350C may directly electrically couple (e.g., directly couple) an exemplary bottom semiconductor die 150B with up to two other bottom semiconductor dies 150. As such, the exemplary bottom semiconductor die 150B may directly communicate with two other bottom semiconductor dies 150. Note that the trient interconnection die 350C may provide electrical coupling to some or all possible pairs of bottom semiconductor dies 150 which the trient interconnection die 350C overlaps (e.g., is bonded to). For example, the trient interconnection die 350C may facilitate up to three communication couplets between the corresponding bottom semiconductor dies 150.

Further illustrated are exemplary electrical paths between the exemplary bottom semiconductor die 150B and other bottom semiconductor dies 150. Analogous versions of the paths P₁, P₂, and P₃ from FIG. 9A are labeled to show communication between the exemplary bottom semiconductor die 150B and some of the proximal bottom semiconductor dies 150. In addition, paths P₄ and P₅ illustrate that basic layout designs may allow a particular interconnection die 350 (e.g., the trient interconnection die 350C) to facilitate communication between three of the bottom semiconductor dies 150. As such, all pairs of the bottom semiconductor dies 150 are within one or two degrees of communication through the trient and quadrant interconnection dies 350C, 350D. It should be appreciated that the interconnection dies 350 (e.g., including the illustrated trient interconnection die 350C) may also facilitate communication between multiple top semiconductor dies 250 whether bonded to same or different bottom semiconductor dies 150.

In FIG. 9C, integrated chip package 100C is illustrated wherein at least one of the interconnection dies 350 is a sextant interconnection die 350F which is electrically coupled to six bottom semiconductor dies 150. As illustrated, the sextant interconnection die 350F may directly electrically couple (e.g., directly couple) an exemplary bottom semiconductor die 150C with up to five other bottom semiconductor dies 150. As such, the exemplary bottom semiconductor die 150C may directly communicate with five other bottom semiconductor dies 150. Note that the sextant interconnection die 350F may provide electrical coupling to some or all possible pairs of bottom semiconductor dies 150 which the sextant interconnection die 350F overlaps (e.g., is bonded to). For example, the sextant interconnection die 350F may facilitate up to fifteen communication couplets between the corresponding bottom semiconductor dies 150.

Further illustrated are exemplary electrical paths between the exemplary bottom semiconductor die 150C and other bottom semiconductor dies 150. Analogous versions of the paths P₁, P₂, and P₃ from FIGS. 9A and 9B are labeled to show communication between the exemplary bottom semiconductor die 150C and some of the proximal bottom semiconductor dies 150. In addition, paths P₄ and P₅ are also made through the sextant interconnection die 350F to distal bottom semiconductor dies 150. As such, all pairs of the bottom semiconductor dies 150 are within one degree of communication through the sextant interconnection die 350F.

In FIG. 9D, integrated chip package 100D is illustrated wherein at least one of the interconnection dies 350 is a quintant interconnection die 350E which is electrically coupled to five bottom semiconductor dies 150. As illustrated, the quintant interconnection die 350E may directly electrically couple (e.g., directly couple) an exemplary interconnection die 150D with up to four other bottom semiconductor dies 150. As such, the exemplary bottom semiconductor die 150D may directly communicate with four other bottom semiconductor dies 150. Note that the quintant interconnection die 350E may provide electrical coupling to some or all possible pairs of bottom semiconductor dies 150 which the quintant interconnection die 350E overlaps (e.g., is bonded to). For example, the quintant interconnection die 350E may facilitate up to ten communication couplets between the corresponding bottom semiconductor dies 150.

Further illustrated are exemplary electrical paths between the exemplary bottom semiconductor die 150D and other bottom semiconductor dies 150. Analogous versions of the paths P₁, P₂, P₃, and P₄, and/or P₅ from FIG. 9C are labeled to show communication between the exemplary bottom semiconductor die 150D and all of the other bottom semiconductor dies 150. In addition, paths P₄ and P₅ illustrate that basic layout designs may allow a particular interconnection die 350 (e.g., the quintant interconnection die 350E) to facilitate communication between five of the bottom semiconductor dies 150. As such, all pairs of the bottom semiconductor dies 150 are within one degree of communication through the quintant interconnection die 350E. As noted above, it can again be appreciated that the interconnection dies 350 (e.g., including the illustrated quintant interconnection die 350E) may also facilitate communication between multiple top semiconductor dies 250 whether bonded to same or different bottom semiconductor dies 150.

Referring to FIGS. 9C and 9D (as well as subsequent FIGS. 9E and 9F), it should be appreciated that some embodiments of the interconnection dies 350E, 350F may electrically couple the distal bottom semiconductor dies 150 while not being directly coupled to the intervening (or interposing) bottom semiconductor dies 150 (e.g., the middle column). For example, the interconnection die 350 may be bonded to the intervening bottom semiconductor dies 150 using the respective dummy bonding pads 323, 223 or entirely through the respective bonding layers 321, 221. These such embodiments highlight a benefit to the flexible package design because the distal bottom semiconductor dies 150 may require (or benefit from) cross-talk when being more proximal (e.g., adjacent as immediate neighbors) is not preferable, reasonable, or feasible. In addition, these distal bottom semiconductor dies 150 may require cross-talk of a relatively less criticality (e.g., less data communication, less frequent communication, less time-sensitive communication, etc.) as compared to some bottom semiconductor dies 150 arranged in closer proximity to one another. Moreover, size and shape preferences or limitations may also play a role.

In FIG. 9E, integrated chip package 100E is illustrated wherein an exemplary bottom semiconductor die 150E and two interconnection dies 350 may provide electrically connectivity to all bottom semiconductor dies 150 within an array. In the illustrated embodiment, two sextant interconnection dies 350F are electrically coupled over four corners of the exemplary bottom semiconductor die 150E. As a result of using the sextant interconnection dies 350F at the particular locations, the bottom semiconductor dies 150 in a three-by-three array have a high electrical connectivity with one another. For example, most of the bottom semiconductor dies 150 are connected to a majority of the other bottom semiconductor dies 150 by a single interconnection die 350F. The other semiconductor pairs can be electrically connected through two interconnection dies 350F.

Moreover, it should be appreciated that each communication between non-adjacent bottom semiconductor dies 150 which requires two interconnection dies 350 has a plurality of electrical paths. For example, any top row bottom semiconductor die 150 can communicate with any bottom row bottom semiconductor die 150 with an electrical connection passing through any middle row bottom semiconductor die 150. As such, three direct paths (e.g., efficient paths passing through a minimal number of dies 150, 350) are possible for any pair of these top row and bottom row bottom semiconductor dies 150. This allows for an increased number of options with package design due to greater flexibility with electrical connectivity between bottom semiconductor dies 150, 250 even when distal from one another.

Further illustrated are exemplary electrical paths between bottom semiconductor dies 150 at opposite corners of the integrated chip package 100E. For example, a signal from the top-left bottom semiconductor die 150 may follow path P_{A} through the upper interconnection die 350F, path P_{B} through the exemplary bottom semiconductor die 150E, and path P_{C} through the lower interconnection die 350F to reach the bottom-right bottom semiconductor die 150, or vice versa.

In FIG. 9F, integrated chip package 100F is illustrated wherein some exemplary dies 150F and three interconnection dies 350 may provide electrically connectivity to all bottom semiconductor dies 150 within an array. In the illustrated embodiment, three sextant interconnection dies 350F are electrically coupled over four corners of each of the exemplary bottom semiconductor dies 150F. As a result of using the sextant interconnection dies 350F at the particular locations, the bottom semiconductor dies 150 in a four-by-three array have a high electrical connectivity with one another. For example, most of the bottom semiconductor dies 150 are connected to a majority of the other bottom semiconductor dies 150 by a single interconnection die 350F. The other semiconductor pairs can be electrically connected through two interconnection dies 350F.

Moreover, it should be appreciated that each communication between non-adjacent bottom semiconductor dies 150 which requires two interconnection dies 350 has a plurality of electrical paths. For example, any first column (e.g., far left column) bottom semiconductor die 150 can communicate with any third or fourth column bottom semiconductor die 150 with an electrical connection passing through any second column bottom semiconductor die 150. As such, at least two or three direct paths are possible for any pair of distal bottom semiconductor dies 150. Similarly as described with previous embodiments, this feature allows for an increased number of options with package design due to greater flexibility with electrical connectivity between bottom semiconductor dies 150, 250 even when distal from one another.

Further illustrated are exemplary electrical paths between bottom semiconductor dies 150 at opposite corners of the integrated chip package 100E. For example, a signal from the top-left bottom semiconductor die 150 may follow path P_{A} through the left interconnection die 350F, path P_{B} through one of the exemplary bottom semiconductor dies 150F, and path P_{C} through the lower-right interconnection die 350F to reach the bottom-right bottom semiconductor die 150, or vice versa.

The embodiments of the present disclosure achieve various advantages. In accordance with various embodiments, the integrated chip package 100 includes bottom semiconductor dies 150, top semiconductor dies 250, and one or more interconnection dies 350. In particular, the bottom semiconductor dies may be formed in a reconstructed wafer, and the top semiconductor dies 250 and the interconnection die 350 are bonded over the bottom semiconductor dies 150. The interconnection die 350 may be bonded to and electrically coupled with three or more of the bottom semiconductor dies 150 in order to facilitate a substantially direct cross-talk communication between all of the corresponding bottom semiconductor dies 150. It should be appreciated that the bottom semiconductor dies 150 may be multi-functional dies (e.g., logic dies) or of high complexity and/or of advanced technology nodes. In any case, the bottom semiconductor dies 150 may benefit from the above-described cross-talk with one another, even when the bottom dies 150 cannot all be adjacent (e.g., immediate neighbors) with one another. As such, the interconnection dies 350 allow for such communication at diagonals, over relatively large distances, and circumventing around (or over) other components of the integrated chip package. As a result, the integrated chip package may be designed with more flexibility of chip configuration, shape, and size, while also benefiting from improvements in function, performance, and reliability.

In an embodiment, a method includes forming a wafer comprising a plurality of bottom dies, the plurality of bottom dies comprising a first bottom die and a second bottom die, the first bottom die and the second bottom die being laterally displaced by a first distance; bonding a first top die to the first bottom die in a face-to-face configuration; bonding a second top die to the second bottom die in a face-to-face configuration, the first top die and the second top die being laterally displaced by a second distance, the second distance being different from the first distance; and bonding an interconnection die to the first bottom die and to the second bottom die in a face-to-face configuration, the interconnection die being interposed between the first top die and the second top die. In another embodiment, the plurality of bottom dies further comprises a third bottom die and a fourth bottom die, and wherein bonding the interconnection die to the first bottom die and to the second bottom die comprises bonding the interconnection die to the third bottom die and the fourth bottom die. In another embodiment, the first bottom die, the second bottom die, the third bottom die, and the fourth bottom die have a quadrant layout, and wherein the interconnection die is electrically interposed between all pairs of the plurality of bottom dies. In another embodiment, the plurality of bottom dies further comprises a fifth bottom die and a sixth bottom die, wherein bonding the interconnection die to the first bottom die, the second bottom die, the third bottom die, and the fourth bottom die comprises bonding the interconnection die to the fifth bottom die and the sixth bottom die, and wherein the interconnection die is electrically interposed between all pairs of the plurality of bottom dies. In another embodiment, the second distance is greater than the first distance. In another embodiment, the interconnection die is laterally displaced from the first top die by a third distance, and wherein the third distance is less than the first distance. In another embodiment, the wafer comprises a reconstructed wafer, wherein an encapsulant separates each of the plurality of bottom dies.

In an embodiment, a method of forming an integrated chip package includes attaching a plurality of bottom dies to a substrate, the plurality of bottom dies comprising a first bottom semiconductor die, a second bottom semiconductor die, and a third bottom semiconductor die arranged in a row; attaching a plurality of top dies over and electrically connected to the plurality of bottom dies, wherein after attaching the plurality of top dies, the first bottom semiconductor die, the second bottom semiconductor die, and the third bottom semiconductor die are electrically isolated from one another; after attaching the plurality of top dies, attaching an interconnection die over the plurality of bottom dies, the interconnection die being electrically connected to the first bottom semiconductor die and the third bottom semiconductor die; removing the substrate from a lower side of the plurality of bottom dies; and attaching a package substrate to the lower side of the plurality of bottom dies. In another embodiment, after attaching the interconnection die: the interconnection die is electrically connected to the second bottom semiconductor die; and each pair of the first bottom semiconductor die, the second bottom semiconductor die, and the third bottom semiconductor die is electrically coupled. In another embodiment, the interconnection die electrically interposes the first bottom semiconductor die and the third bottom semiconductor die. In another embodiment, the interconnection die directly electrically interposes the first bottom semiconductor die and the third bottom semiconductor die. In another embodiment, after attaching the interconnection die and before attaching the package substrate, the second bottom semiconductor die remains electrically isolated from the first bottom semiconductor die and the third bottom semiconductor die.

In an embodiment, a semiconductor device includes a first bottom semiconductor die and a second bottom semiconductor die disposed over a package substrate; an encapsulant disposed between and surrounding the first bottom semiconductor die and the second bottom semiconductor die, the encapsulant being bonded to a first semiconductor substrate of the first bottom semiconductor die and to a second semiconductor substrate of the second bottom semiconductor die, the encapsulant being coterminous with the first semiconductor substrate and the second semiconductor substrate; a first top semiconductor die disposed over and electrically connected to the first bottom semiconductor die; a second top semiconductor die disposed over and electrically connected to the second bottom semiconductor die; and an interconnection die disposed over and electrically connected to the first bottom semiconductor die and the second bottom semiconductor die, in a plan view the interconnection die overlapping a first corner of the first bottom semiconductor die. In another embodiment, each of the first bottom semiconductor die, the second bottom semiconductor die, the first top semiconductor die, and the second top semiconductor die comprises at least one transistor, and wherein the interconnection die is free of transistors. In another embodiment, in the plan view the interconnection die overlaps a second corner of the second bottom semiconductor die. In another embodiment, a portion of the interconnection die extends directly between the first top semiconductor die and the second top semiconductor die. In another embodiment, a first distance between the first bottom semiconductor die and the second bottom semiconductor die is less than a second distance between the first top semiconductor die and the second top semiconductor die, and wherein the first distance is greater than a third distance between the interconnection die and the first top semiconductor die. In another embodiment, the semiconductor device further includes a third bottom semiconductor die and a fourth bottom semiconductor die disposed over the package substrate, wherein the interconnection die is disposed over and electrically connected to the third bottom semiconductor die and the fourth bottom semiconductor die. In another embodiment, all pairs of the first bottom semiconductor die, the second bottom semiconductor die, the third bottom semiconductor die, and the fourth bottom semiconductor die are electrically coupled by the interconnection die. In another embodiment, the semiconductor device further includes a fifth bottom semiconductor die and a sixth bottom semiconductor die disposed over the package substrate, wherein the interconnection die is disposed over and electrically connected to the fifth bottom semiconductor die and the sixth bottom semiconductor die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a wafer comprising a plurality of bottom dies, the plurality of bottom dies comprising a first bottom die and a second bottom die, the first bottom die and the second bottom die being laterally displaced by a first distance;
bonding a first top die to the first bottom die in a face-to-face configuration;
bonding a second top die to the second bottom die in a face-to-face configuration, the first top die and the second top die being laterally displaced by a second distance, the second distance being different from the first distance; and
bonding an interconnection die to the first bottom die and to the second bottom die in a face-to-face configuration, the interconnection die being interposed between the first top die and the second top die.

2. The method of claim 1, wherein the plurality of bottom dies further comprises a third bottom die and a fourth bottom die, and wherein bonding the interconnection die to the first bottom die and to the second bottom die comprises bonding the interconnection die to the third bottom die and the fourth bottom die.

3. The method of claim 2, wherein the first bottom die, the second bottom die, the third bottom die, and the fourth bottom die have a quadrant layout, and wherein the interconnection die is electrically interposed between all pairs of the plurality of bottom dies.

4. The method of claim 2, wherein the plurality of bottom dies further comprises a fifth bottom die and a sixth bottom die, wherein bonding the interconnection die to the first bottom die, the second bottom die, the third bottom die, and the fourth bottom die comprises bonding the interconnection die to the fifth bottom die and the sixth bottom die, and wherein the interconnection die is electrically interposed between all pairs of the plurality of bottom dies.

5. The method of claim 1, wherein the second distance is greater than the first distance.

6. The method of claim 1, wherein the interconnection die is laterally displaced from the first top die by a third distance, and wherein the third distance is less than the first distance.

7. The method of claim 1, wherein the wafer comprises a reconstructed wafer, wherein an encapsulant separates each of the plurality of bottom dies.

8. A method of forming an integrated chip package, the method comprising:
attaching a plurality of bottom dies to a substrate, the plurality of bottom dies comprising a first bottom semiconductor die, a second bottom semiconductor die, and a third bottom semiconductor die arranged in a row;
attaching a plurality of top dies over and electrically connected to the plurality of bottom dies, wherein after attaching the plurality of top dies, the first bottom semiconductor die, the second bottom semiconductor die, and the third bottom semiconductor die are electrically isolated from one another;
after attaching the plurality of top dies, attaching an interconnection die over the plurality of bottom dies, the interconnection die being electrically connected to the first bottom semiconductor die and the third bottom semiconductor die;
removing the substrate from a lower side of the plurality of bottom dies; and
attaching a package substrate to the lower side of the plurality of bottom dies.

9. The method of claim 8, wherein after attaching the interconnection die:
the interconnection die is electrically connected to the second bottom semiconductor die; and
each pair of the first bottom semiconductor die, the second bottom semiconductor die, and the third bottom semiconductor die is electrically coupled.

10. The method of claim 9, wherein the interconnection die electrically interposes the first bottom semiconductor die and the third bottom semiconductor die.

11. The method of claim 10, wherein the interconnection die directly electrically interposes the first bottom semiconductor die and the third bottom semiconductor die.

12. The method of claim 8, wherein after attaching the interconnection die and before attaching the package substrate, the second bottom semiconductor die remains electrically isolated from the first bottom semiconductor die and the third bottom semiconductor die.

13. A semiconductor device, comprising:
a first bottom semiconductor die and a second bottom semiconductor die disposed over a package substrate;
an encapsulant disposed between and surrounding the first bottom semiconductor die and the second bottom semiconductor die, the encapsulant being bonded to a first semiconductor substrate of the first bottom semiconductor die and to a second semiconductor substrate of the second bottom semiconductor die, the encapsulant being coterminous with the first semiconductor substrate and the second semiconductor substrate;
a first top semiconductor die disposed over and electrically connected to the first bottom semiconductor die;
a second top semiconductor die disposed over and electrically connected to the second bottom semiconductor die; and
an interconnection die disposed over and electrically connected to the first bottom semiconductor die and the second bottom semiconductor die, in a plan view the interconnection die overlapping a first corner of the first bottom semiconductor die.

14. The semiconductor device of claim 13, wherein each of the first bottom semiconductor die, the second bottom semiconductor die, the first top semiconductor die, and the second top semiconductor die comprises at least one transistor, and wherein the interconnection die is free of transistors.

15. The semiconductor device of claim 13, wherein in the plan view the interconnection die overlaps a second corner of the second bottom semiconductor die.

16. The semiconductor device of claim 13, wherein a portion of the interconnection die extends directly between the first top semiconductor die and the second top semiconductor die.

17. The semiconductor device of claim 13, wherein a first distance between the first bottom semiconductor die and the second bottom semiconductor die is less than a second distance between the first top semiconductor die and the second top semiconductor die, and wherein the first distance is greater than a third distance between the interconnection die and the first top semiconductor die.

18. The semiconductor device of claim 13, further comprising a third bottom semiconductor die and a fourth bottom semiconductor die disposed over the package substrate, wherein the interconnection die is disposed over and electrically connected to the third bottom semiconductor die and the fourth bottom semiconductor die.

19. The semiconductor device of claim 18, wherein all pairs of the first bottom semiconductor die, the second bottom semiconductor die, the third bottom semiconductor die, and the fourth bottom semiconductor die are electrically coupled by the interconnection die.

20. The semiconductor device of claim 18, further comprising a fifth bottom semiconductor die and a sixth bottom semiconductor die disposed over the package substrate, wherein the interconnection die is disposed over and electrically connected to the fifth bottom semiconductor die and the sixth bottom semiconductor die.
